(19) United States
(12) Patent Application Publication
(10) Pub. No.: US 2005/0045898 A1
(43) Pub. Date: Mar. 3, 2005

(54) Light-emitting diode and backlight system using the same

(76) Inventors: Charles Leu, Fremont, CA (US); Tai-cherng Yu, Tu-chen (TW); Ga-Lane Chen, Fremont, CA (US)

Correspondence Address: WEI TE CHUNG;FOXCONN INTERNATIONAL, INC., 1650 MEMOREX DRIVE, SANTA CLARA, CA, 95050, US

(21) Appl. No.: 10/933,724

(22) Filed: Sep. 3, 2004

(30) Foreign Application Priority Data
Sep. 3, 2003 (TW) 92124278

(51) Int. Cl. H01L 21/00; H01L 29/22

(52) U.S. Cl. 257/98; 257/100; 438/22; 438/25

(57) ABSTRACT

A light-emitting diode (LED) (10) includes a chip body (103), an encapsulation can (105) surrounding the chip body, and a base (106) supporting the encapsulation can and the chip body thereon. Numerous diffusion structures (1050) are provided on the encapsulation can. With the diffusion structures, light beams from the chip body are diffused and attain wider irradiation angles. A backlight system (900) includes a light guide plate (20), and a number of LEDs as per the above. The LEDs are disposed adjacent to the light guide plate. Light beams having wide irradiation angles are emitted from the LEDs and enter the light guide plate. This enables a light exit surface of the light guide plate to have highly uniform brightness.

### BACKGROUND OF THE INVENTION

1. Field of the Invention

The present invention relates to point light sources, and particularly to a light-emitting diode (LED) and a backlight system of a liquid crystal display (LCD) using the LED.

2. Description of the Prior Art

Referring to FIG. 4, a conventional LED 1 typically comprises a base 16, a chip body 13 and an encapsulation can 15. The chip body 13 is fixed on the base 16, and the encapsulation can 15 is also fixed on the base 1 such that the encapsulation can 15 surrounds and seals the chip body 13.

In general, the LED 1 emits light beams which have a very small radiation angle. Turning to FIG. 5, a plurality of the LEDs 1 is used as light sources of a backlight system 90. Even though the LEDs 1 provide a bright illumination for a light exit surface 23 of a light guide plate 2 of the backlight system 90, certain dark areas 22 tend to exist at the light exit surface 23 adjacent the LEDs 1. A typical liquid crystal display depends on the backlight system 90 to provide highly uniform brightness over the entire area of the light exit surface 23. When the back light system 90 provides poor quality optical performance, the performance of the liquid crystal display is correspondingly unsatisfactory.

### SUMMARY OF THE INVENTION

An object of the present invention is to provide an LED which emits light beams having a wide radiation angle.

Another object of the present invention is to provide a backlight system which can provide excellent uniformity of brightness for a liquid crystal display.

According to a first aspect of the present invention, there is provided an LED comprising a chip body, an encapsulation can surrounding the chip body, and a base supporting the encapsulation can and the chip body thereon. A plurality of diffusion structures is provided on the encapsulation can. With the diffusion structures, light beams from the chip body are diffused and attain wider irradiation angles.

According to a second aspect of the present invention, there is provided a backlight system comprising a light guide plate, and a plurality of LEDs according to the above-described LED. The LEDs are disposed adjacent to the light guide plate. Light beams having wide irradiation angles are emitted from the LEDs and enter the light guide plate. This enables a light exit surface of the light guide plate to have highly uniform brightness.

Other objects, advantages, and novel features of the present invention will be apparent from the following detailed description of preferred embodiments thereof with reference to the attached drawings.

### BRIEF DESCRIPTION OF THE DRAWINGS

FIG. 1 is a schematic, cross-sectional view of an LED according to a preferred embodiment of the present invention, the cross-section corresponding to an imaginary straight line drawn through a middle of the LED.

FIG. 2 is an enlarged view of a circled portion II of FIG. 1.

FIG. 3 is a bottom plan view of a backlight system incorporating three of the LEDs of FIG. 1, according to the present invention.

FIG. 4 is a schematic, cross-sectional view a conventional LED.

FIG. 5 is a schematic, top plan view of a backlight system incorporating three of the LEDs of FIG. 4, showing light paths in a light guide plate of the backlight system.

### DETAILED DESCRIPTION OF THE PRESENT INVENTION

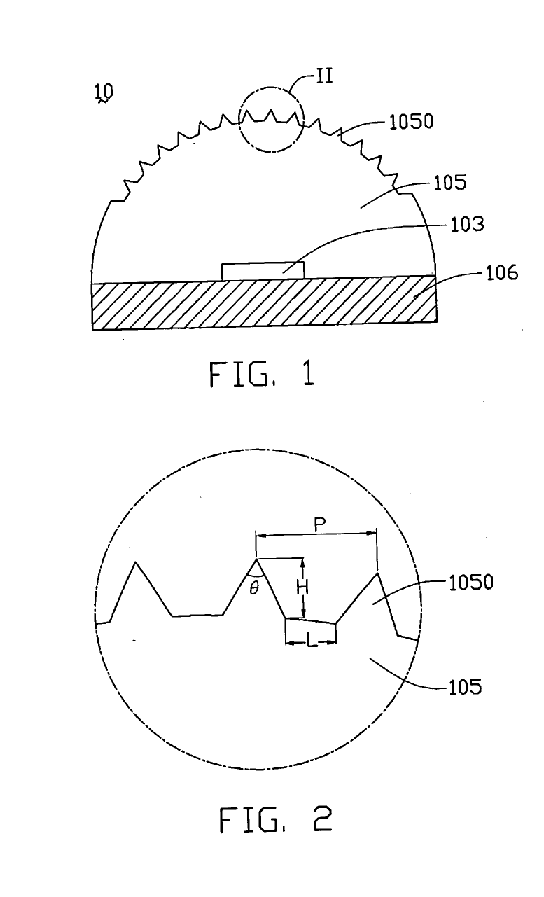

Referring to FIG. 1, an LED 10 according to the preferred embodiment of the present invention comprises a chip body 103 for emitting light, an encapsulation can 105 surrounding the chip body 103, and a base 106 supporting the encapsulation can 105 and the chip body 103. The encapsulation can 105 has a plurality of substantially V-shaped members 1050 arranged thereon in a regular array.

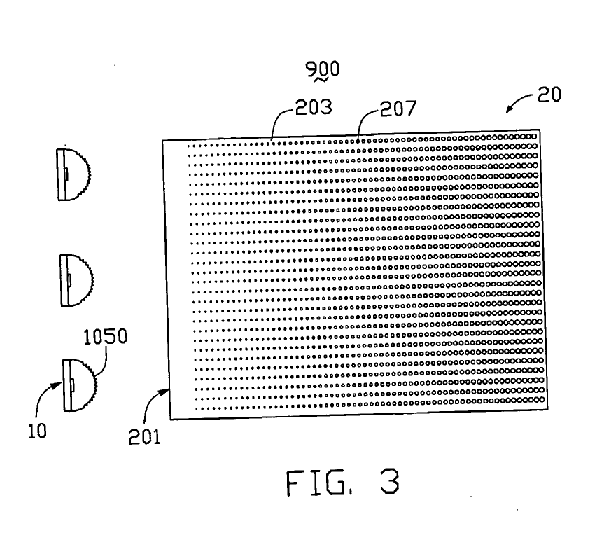

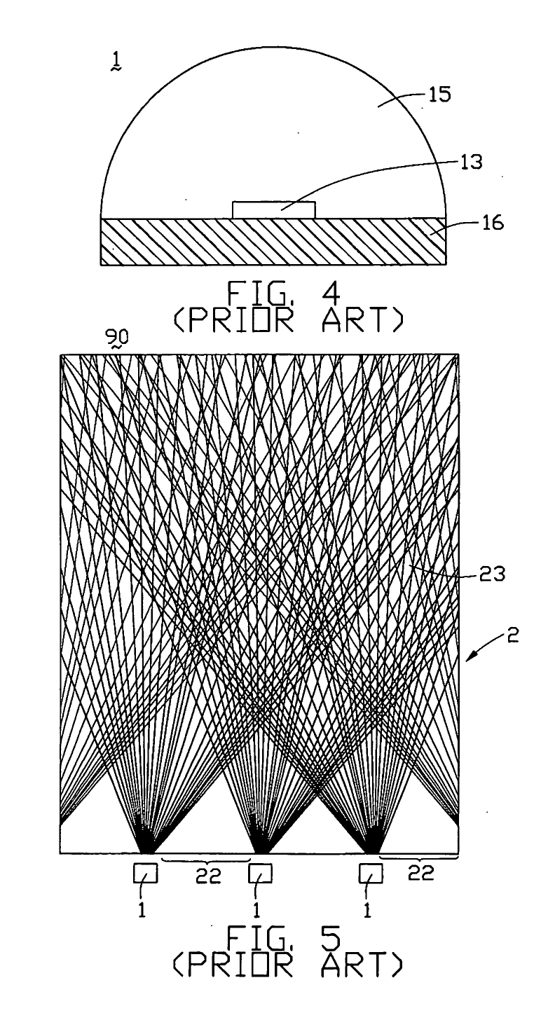

Referring to FIG. 2, a pitch between apexes (not labeled) of two adjacent V-shaped members 1050 is defined as P, a distance separating two adjacent V-shaped members 1050 is defined as L, a height of the V-shaped members 1050 is defined as H, and a vertex angle of the V-shaped members 1050 is defined as θ. In order to attain good optical performance, the following specifications are provided. P is in the range from 1 to 50 μm, and is preferably 50 μm. L is in the range from 1 to 30 μm, and is preferably 30 μm. H is in the range from 1 to 10 μm, and is preferably 10 μm. θ is in the range from 75 degrees to 145 degrees, and is preferably 145 degrees.

The V-shaped members 1050 are manufactured by a precision cutting method. Alternatively, the V-shaped members 1050 can be manufactured by a projection molding method.

The chip body 103 is made of semiconductor material that can emit photons when electricity is supplied. The encapsulation can 105 is formed of a transparent or translucent resin.

Referring to FIG. 3, a backlight system 900 incorporating the above-described LED 10 comprises a light guide plate 20, and a plurality of the LEDs 10 disposed adjacent to the light guide plate 20.

The light guide plate 20 is substantially flat and rectangular, and has a light incident surface 201, a light exit surface (not labeled), and a bottom surface 203 opposite to the light exit surface. To improve optical performance, a multiplicity of pattern-dots 207 is disposed on the bottom surface 203 in a regular array. The pattern-dots 207 may, for example, be hemispherical.

In assembly of each LED 10, the chip body 103 is installed on the base 106. The encapsulation can 105 is installed on the base 106 to surround and seal the chip body 103. In assembly of the backlight system 900, the LEDs 10 are placed beside the light guide plate 20, with the V-shaped members 1050 positioned adjacent to the light incident surface 201 of the light guide plate 20.

In operation of the backlight system 900, the chip bodies 103 emit light beams (not shown), which pass through the encapsulation cages 105 and the V-shaped members 1050. The V-shaped members 1050 diffuse the light beams, thereby widening an irradiation angle of the LEDs 10. The light beams transmit through the light incident surface 201 into the light guide plate 20, and are output from the light exit surface of the light guide plate 20. Compared with the above-described conventional back light system 90, the light beams emitting from the LEDs 10 have wider irradiation angles. The dark areas 22 found in the conventional back light system 90 are not present in the back light system 900. The back light system 900 obtains excellent uniformity of brightness at the light exit surface, and provides excellent uniformity of brightness for a liquid crystal display.

Many modifications and variations are possible within the ambit of the invention herein. For example, the V-shaped members 1050 can instead be Fresnel lens or convex protrusions. The number of the chip bodies 103 for each LED 10 is not necessarily limited to one. The light guide plate 20 can alternatively be wedge-shaped. The backlight system 900 may further include a diffusion sheet and a prism sheet. All such and other modifications and variations that may be apparent to a person of ordinary skill in the art are intended to be within the scope of the present invention.

It is to be further understood that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. A light-emitting diode comprising:
a chip body for emitting light;
an encapsulation can for surrounding and protecting the chip body; and
a base for supporting the chip body and the encapsulation can;
wherein a plurality of diffusion structures is provided on the encapsulation can for widening irradiation angles of optical beams emitted from the chip body.

2. The light-emitting diode as claimed in claim 1, wherein the diffusion structures are V-shaped members.

3. The light-emitting diode as claimed in claim 2, wherein a pitch between top portions of two adjacent V-shaped members is in the range from 1 to 50 μm.

4. The light-emitting diode as claimed in claim 2, wherein a vertex angle of the V-shaped members is in the range from 75 degrees to 145 degrees.

5. The light-emitting diode as claimed in claim 2, wherein a height of the V-shaped members is in the range from 1 to 10 μm.

6. The light-emitting diode as claimed in claim 2, wherein a distance separating two adjacent V-shaped members is in the range from 1 to 30 μm.

7. The light-emitting diode as claimed in claim 1, wherein the diffusion structures are Fresnel lens.

8. The light-emitting diode as claimed in claim 1, wherein the diffusion structures are convex protrusions.

9. A backlight system comprising:
at least one light-emitting diode comprising a base, a chip body mounted on the base, and an encapsulation can mounted on the base, the encapsulation can having a plurality of diffusion structures provided thereon; and
a light guide plate comprising a light incident surface positioned adjacent to the diffusion structures in order to receive light beams therefrom, and a light exit surface.

10. The backlight system as claimed in claim 9, wherein the light guide plate further comprises a bottom surface opposite to the light exit surface, and the bottom surface has a multiplicity of pattern-dots arranged in a regular array provided thereon.

11. The backlight system as claimed in claim 9, wherein the diffusion structures are V-shaped members.

12. The backlight system as claimed in claim 9, wherein a pitch between top portions of two adjacent V-shaped members is in the range from 1 to 50 μm, a vertex angle of the V-shaped members is in the range from 75 degrees to 145 degrees, a height of the V-shaped members is in the range from 1 to 10 μm, and a distance separating two adjacent V-shaped members is in the range from 1 to 30 μm.

13. The backlight system as claimed in claim 9, wherein the diffusion structures are Fresnel lens.

14. The backlight system as claimed in claim 9, wherein the diffusion structures are convex protrusions.

15. A light-emitting diode comprising:
a chip body for emitting light; and
an encapsulation can spatially surrounding and protecting the chip body; wherein
a plurality of diffusion structures is provided on the encapsulation can for widening irradiation angles of optical beams emitted from the chip body.

16. The light-emitting diode as claimed in claim 15, wherein the diffusion structures are essentially a series of gear-like protrusions extending along a portion of a circumference with a center where the chip body is located.

17. The light-emitting diode as claimed in claim 16, wherein said gear-like protrusions define apexes on top portions and flat faces on bottom portions.
